(19) United States
(12) Patent Application Publication
(10) Pub. No.: US 2006/0191783 A1
(43) Pub. Date: Aug. 31, 2006

(54) Method and apparatus for forming adherent metal film on a polymer substrate

(76) Inventors: Yeon Hee Lee, Seoul (KR); Seung Hee Han, Seoul (KR)

Correspondence Address: JONES DAY, 222 EAST 41ST ST, NEW YORK, NY, 10017, US

(21) Appl. No.: 11/365,999

(22) Filed: Feb. 28, 2006

(30) Foreign Application Priority Data
Feb. 28, 2005 (KR) 10-2005-0016366

(51) Int. Cl. C23C 14/32; C23C 14/00

(52) U.S. Cl. 204/192.1; 204/298.02

(57) ABSTRACT

There is provided a method and an apparatus for forming an adherent metal-thin film on a polymer substrate in a simple and efficient manner, wherein said film has a superior adhesion to the polymer substrate. In accordance with the method of the present invention, a metal film may be deposited on a polymer substrate with implanting plasma ions in a polymer substrate so as to form a gradient interfacial layer in which the metal and polymer particles are mixed between metal and polymer layers, thereby markedly enhancing the adhesion of a metal film to a polymer substrate.

### FIELD OF THE INVENTION

The present invention generally relates to a method and apparatus for forming an adherent metal-thin film on a polymer substrate, and more particularly to a method and apparatus adapted to form a metal-thin film having superior adhesion to a polymer substrate in a simple and efficient manner.

### BACKGROUND OF THE INVENTION

Polymeric materials are widely used in various fields. This is because they exhibit useful characteristics such as lightweight, moldability, workability, transparency, electrically insulating properties and the like. Polymeric materials having a metal-conduction layer, which is attached to at least one surface thereof, are used in various microelectronic industries (e.g., printed wiring boards, printed circuit boards, magnetic materials, optical materials, ultra large scale integrated semiconductor devices, etc.). However, there is a problem in that a metal layer is readily detached from the surface of a polymer substrate due to its low adhesion to the polymeric material when the metal-thin film is formed on the polymeric material.

Thus, various methods have been developed and introduced in order to improve the adhesion of a metal film to a polymer substrate.

For example, there has been developed a method for electrolytic or non-electrolytic plating a metal film on a polymer substrate via a chemical pre-treatment of the surface of a polymer substrate (e.g., with sodium naphthalenide) so as to enhance the adhesion of a metal film to a polymer substrate (Korean Patent No. 10-0293532).

However, such method needs to perform several surface-treatment steps and use various aqueous chemical solutions, which are required for accompanying equipments for wastewater treatment. Thus, the processing cost is quite high.

Further, Great Britain Patent No. 1 370 893 discloses a method of enhancing the adhesion between the metal and polymer materials by heating the metal coated-polymer product. Also, Japanese Patent Nos. 80-4583 and 80-12870 introduce a method of improving the adhesion of a metal film to a polymer substrate, which employs a polymeric adhesive layer (e.g., co-polyester resin layer) between the metal and polymer layers. Unfortunately, however, such adhesion is not very durable especially when the metal-coated polymer products are in highly humid conditions, thereby limiting their applications.

Attempts have also been made to improve adhesion between the metal and polymer materials by cleaning or chemically roughening the surface of a polymer substrate by using a plasma and an ion gun, exposing a polymer substrate to a reactive gas plasma to form reactive functional groups on the substrate surface, or depositing an adhesive layer of Ti, Cr or Ni onto the polymer substrate prior to metal deposition thereon (F. Milde et al., Thin Solid Films, page 169, 1996).

However, in such methods, the adhesion of metal to polymer substrate is markedly reduced when the metal-coated polymer product is heat-treated.

### SUMMARY OF THE INVENTION

It is a primary object of the present invention to provide a method and apparatus for forming a metal film on a polymer substrate in a simple and efficient manner, wherein said metal film has a superior adhesion to the polymer substrate.

In accordance with one aspect of the present invention, there is provided a method of forming an adherent metal-thin film on a polymer substrate, which comprises the following steps: a) placing a polymer substrate on a conductive sample-holding stage installed within a vacuum chamber; b) introducing a plasma-source gas into the vacuum chamber containing the polymer substrate; c) producing a plasma from the plasma-source gas; d) vapor depositing metal particles on the polymer substrate by applying a negative voltage to the metal target installed at upper side of the sample-holding stage within the vacuum chamber; and e) implanting plasma ions in the surface of the polymer substrate by applying a negative high-voltage pulse to the polymer substrate.

In accordance with another aspect of the present invention, there is provided an apparatus for forming an adherent metal-thin film on a polymer substrate, comprising: a vacuum chamber (1) and a vacuum pump (2) which are earthed in the electric grounding (12); a gas inlet (10) for introducing a plasma-source gas (11) into the vacuum chamber (1); an antenna (5), a radio frequency (RF) power unit (3) and a matching network (4) for generating a plasma from the plasma-source gas (11); a conductive sample-holding stage (8) for supporting a polymer substrate (7) to which a negative high-voltage pulse is applied such that positively charged plasma ions are implanted in the polymer substrate (7); a high-voltage pulse generator (9) from which the high-voltage pulse for implanting plasma ions in the polymer substrate is supplied; a metal target (13) in which a metal source is fixed; and a power supply (14) for supplying a negative voltage to the metal target (13).

### BRIEF DESCRIPTION OF THE DRAWINGS

The above and other objects and features of the present invention will become apparent from the following description of preferred embodiments given in conjunction with the accompanying drawings, in which:

FIG. 1 is a schematic diagram showing an example of an apparatus for forming an adherent metal film on a polymer substrate in accordance with the present invention;

FIGS. 2a and 2b are graphs showing the relationships between the voltages applied to a metal target and a polymer substrate in the present invention;

FIG. 3 is a graph showing the peel strengths of the metal films deposited via non-treatment and plasma treatment of the polymer substrate, and while implanting plasma ions in the polymer substrate in Example 1 of the present invention;

FIG. 4 is a graph showing the peel strengths of the metal films according to the changes of the plasma-source gases, which are used in Example 2 of the present invention;

FIG. 5 is a graph showing the peel strengths of the metal films as a function of time for implanting plasma ions in the polymer substrate in Example 3 of the present invention; and

FIGS. 6a and 6b are graphs showing Auger distributions according to the depth of the metal films deposited via plasma treatment of the polymer substrate and while implanting plasma ions in the polymer substrate in Example 4 of the present invention, respectively.

### DETAILED DESCRIPTION OF THE PRESENT INVENTION

The method of the present invention is characterized by adopting a metal depositing process such as a sputtering process and a process for implanting plasma ions in a polymer substrate so as to form a gradient interfacial layer in which the metal and polymer particles are mixed between the metal film and polymer substrate layers. This results in remarkable enhancement of the adhesion of a metal film to a polymer substrate.

The present invention is described below in detail.

According to the present invention, a metal film may be deposited on a polymer substrate by applying a negative voltage to the metal so as to sputter metal particles and applying a high-voltage pulse to the polymer substrate in order to implant plasma ions on the surface thereof under a gaseous plasma atmosphere.

In the method of the present invention, the metal deposition process and the plasma-ion implantation process may be performed simultaneously or in an alternating manner.

The process of the present invention may be performed as follows:

In step a), a polymer substrate, which is to be coated with a metal, and a metal target are placed within a vacuum chamber. The polymer substrate is disposed on a conductive sample-holding stage installed within the vacuum chamber and the metal target is installed at upper side of the sample-holding stage.

Exemplary metals, which may be used in the present invention, include, but not limited to, gold, silver, aluminum, stainless steel and the like.

The suitable polymer, which may be used as a polymer substrate to be coated with the metal in the present invention, include, but not limited to, polyimide, polyethylene terephthalate, polycarbonate, poly(tetrafluoroethylene), polypropylene, polyethylene and the like.

Once an appropriate vacuum level is reached, in step b), a plasma-source gas is introduced into the chamber containing a polymer substrate and a metal target.

The plasma-source gas, which may be used in the present invention, includes all gases capable of generating plasma. For example, argon, helium, neon, krypton, xenon and mixtures thereof may be employed. However, it should not be limited to the above examples.

In step c), a plasma is generated from the plasma-source gas by applying a radio frequency (RF) wave having a frequency of 1 to 27 MHz and a power of 20 W to 2 kW to an antenna in the chamber.

The metal deposition of step d) may be performed by applying a negative direct current (DC) voltage ranging from −100 V to −2 kV, or a negative pulse voltage having a pulse width ranging from 1 to 999 ms, to the metal target.

In this step, the metal-thin film is deposited on the surface of the polymer substrate by sputtering process. The sputtering process comprises ionizing the gaseous plasma so that the positively charged plasma ions are accelerated to the negatively charged metal target where they impinge upon the surface of the metal target and cause the release of the metal atoms. The released metal atoms are deposited on the surface of the polymer substrate.

Further, the plasma-ions implantation of step e) may be performed by applying a negative high-voltage pulse having a voltage ranging from −500 V to −50 kV, a pulse-off voltage ranging from 0 V to −1 kV, a pulse width ranging from 1 to 100 μs and a pulse frequency ranging from 10 Hz to 10 kHz for the implantation time ranging from 10 seconds to 2 hours, to the polymer substrate.

In this step, the applied negative voltage pulse should have a high energy sufficient to implant plasma ions into the surface of the polymer substrate. This step also comprises ionizing the gaseous plasma so that the positively charged plasma ions are implanted in the surface of the polymer substrate. The plasma ions may be implanted with having corresponding energies applied to the polymer substrate, which allows the metal and polymer particles to be mixed on the periphery of the interface of a polymer substrate and a metal film. This results in the formation of a gradient interfacial layer (i.e., a metal-polymer mixed layer) between a metal film and a polymer substrate. Thus, the adhesion of a metal film to a polymer substrate is markedly enhanced when compared with the laminate of a metal film and a polymer substrate having no metal-polymer mixed interfacial layer.

The metal deposition step d) and the plasma-ion implantation step e) may be performed at the same time. Alternatively, the plasma-ion implantation step e) may be performed in a predetermined time (e.g., within 1 hour) after the metal deposition step d) is initiated.

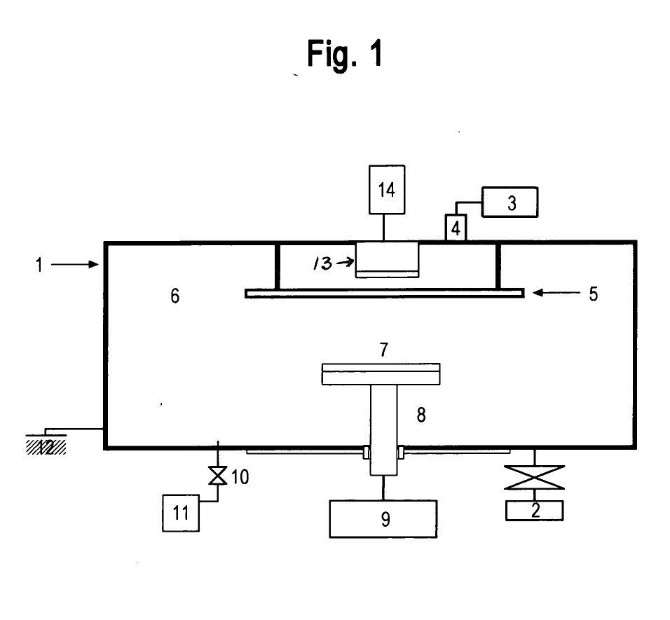

FIG. 1 illustrates an example of the apparatus for depositing an adherent metal-thin film on the surface of a polymer substrate according to the present invention. Referring to FIG. 1, the apparatus of the present invention comprises: a vacuum chamber (1) and a vacuum pump (2) which are earthed in the electric grounding (12); a gas inlet (10) for introducing a plasma-source gas (11) into the vacuum chamber (1); an antenna (5), a radio frequency (RF) power unit (3) and a matching network (4) for generating a plasma from the plasma-source gas (11); a conductive sample-holding stage (8) for supporting a polymer substrate (7) to which a negative high-voltage pulse is applied such that positively charged plasma ions are implanted in the polymer substrate (7); a high-voltage pulse generator (9) from which the high-voltage pulse for implanting plasma ions in the polymer substrate is supplied; a metal target (13) in which a metal source is fixed; and a power supply (14) for supplying a negative voltage to the metal target (13).

The plasma-source gas, which is used for forming a gradient interface between a metal film and a polymer substrate in the present invention, includes, but not limited to argon, helium, neon, krypton, xenon, mixtures thereof and the like. In addition, the implantation of plasma ions in a polymer substrate may be conducted by using a RF plasma, which is generated using the antenna (5), the matching network (4) and the RF power supply-unit (3) in the vacuum chamber. A metal-thin film may be vapor deposited on a polymer substrate (7) by applying a negative DC- or pulse-voltage to the metal target (13).

The high-voltage pulse, which is applied to the polymer substrate for implanting plasma ions therein in the present invention, may have a voltage of −500 V to −50 kV, a pulse-off voltage of 0 V to −1 kV, a pulse width of 1 to 100 μs and a pulse frequency of 10 Hz to 10 kHz. Further, the plasma ion-implantation time may be in the range of 10 seconds to 2 hours. Also, the voltage, which is applied to the metal target for depositing metal particles on a polymer substrate in the present invention, is preferably a DC voltage of −100 V to −2 kV or a pulse voltage having a pulse width of 1 to 999 ms.

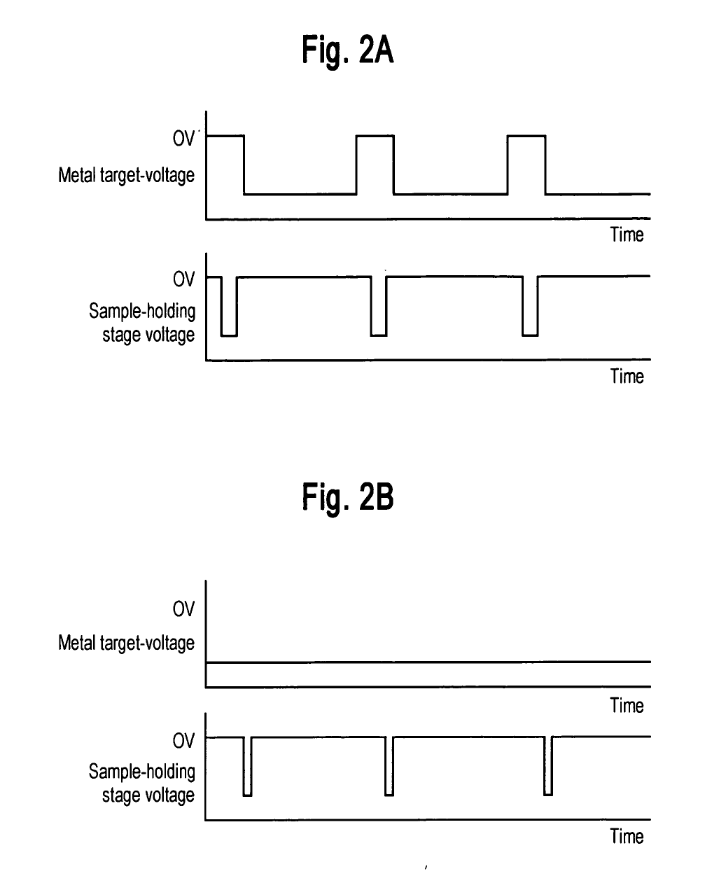

The relationships between the voltages, which are applied to a metal target and a polymer substrate, are shown in FIGS. 2a and 2b. FIG. 2a is a graph showing variations of the applied voltages as a function of time when pulse voltages are applied to a metal target and a polymer substrate in turn. Further, FIG. 2b is a graph showing variations of the applied voltages as a function of time when a direct current (DC) voltage is applied to a metal target and a pulse voltage is applied to a polymer substrate.

The plasma-ion implantation process may be conducted when initiating the metal-deposition process or within 1 hour after initiating the metal-deposition process.

In accordance with the method of the present invention, a metal-thin film having superior adhesion to a polymeric material can be prepared in a simple and efficient manner by vapor depositing a metal film on a polymer substrate with the implantation of plasma ions in the polymer substrate so as to form a gradient interfacial layer (i.e., a metal-polymer mixed interface) between the metal and polymer layers. Such superior adhesion can be maintained even after being subjected to subsequent processes (e.g., heat-treatment process) since the metal-coated polymer product has an interface in which the metal and polymer particles are mixed.

Also, according to the present invention, there is no need to perform a separate process for depositing a polymeric adhesive layer or tie coat between a metal film and a polymer substrate, which causes increase of processing time. Further, the method of the present invention can be performed using a simple apparatus as shown in FIG. 1, and can deposit a metal-thin film on a large area of a polymer substrate without limiting the shapes thereof. Thus, the method of the present invention can be advantageously used for preparing a large size product having an adherent metal-thin film layer on a polymer substrate.

The present invention is further described and illustrated in the Examples provided below. However, it should be expressly noted herein that the Examples are not intended to limit the scope of the present invention.

### EXAMPLE 1

A polyimide substrate, which is cut into a 70 mm (width)×70 mm (length)×0.1 mm (thickness) piece, was placed on a conductive sample-holding stage installed in a 100 liter-vacuum chamber as shown in FIG. 1. The pressure in the chamber was decreased to a level of 2×10⁻⁵ torr or less using a vacuum system composed of a rotary pump and a turbo pump. Then, an argon gas was introduced at a flow rate of 3 sccm into the chamber to a pressure of 1 mtorr and a plasma was produced therefrom using a RF wave (CESAR 136, Dressler) having a frequency of 13.56 MHz and a power of 200 W. Subsequently, the DC voltage of −1 kV was applied to the copper target for 1 hour so as to vapor deposit a copper-thin film on the surface of polyimide substrate, while implanting plasma ions in the polyimide substrate by way of applying a pulse having a pulse width of 20 μs and a pulse frequency of 100 Hz to the sample-holding stage for 15 minutes.

In terms of peel strength, the adhesion of the copper film to the polyimide substrate was determined by the conventional 90° peel test. The 90° peel test was performed by measuring the strength (N/m) for peeling off the copper film in a 90° direction from the polyimide substrate with a constant force.

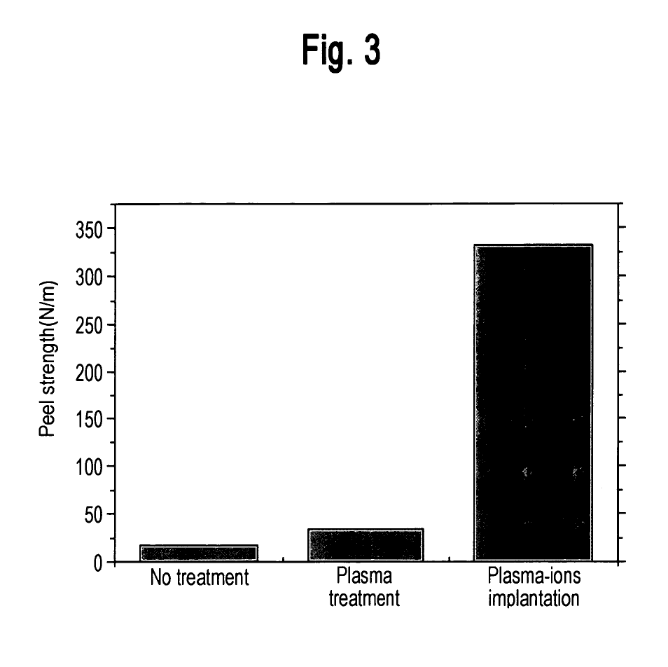

Further, the adhesion of the copper films as comparative films, which are deposited on polyimide substrates via non-treatment and pre-cleaning of the polyimide substrate using plasma instead of implanting plasma ions therein were also determined according to the same method described above. The results are shown in FIG. 3.

As shown in FIG. 3, the peel strength of the copper film to a polyimide substrate was greater than 330 N/m when deposited while implanting plasma ions in the polyimide substrate in accordance with the present invention. However, the comparative copper films deposited without implanting plasma ions in the polyimide substrate, but with plasma pre-cleaning or non-plasma treatment of the polyimide substrate were readily peeled off from the substrate.

### EXAMPLE 2

The procedure of Example 1 was repeated except that the polyimide substrate of a 70 mm (width)×70 mm (length)×0.2 mm (thickness) piece was used; an argon, helium, neon or xenon gas was introduced as a plasma-source gas at a flow rate of 3 to 5 sccm into the vacuum chamber; and the pulse having a pulse voltage of −20 kV, a pulse width of 20 μs and a pulse frequency of 500 Hz was applied to the polyimide substrate on a sample-holding stage.

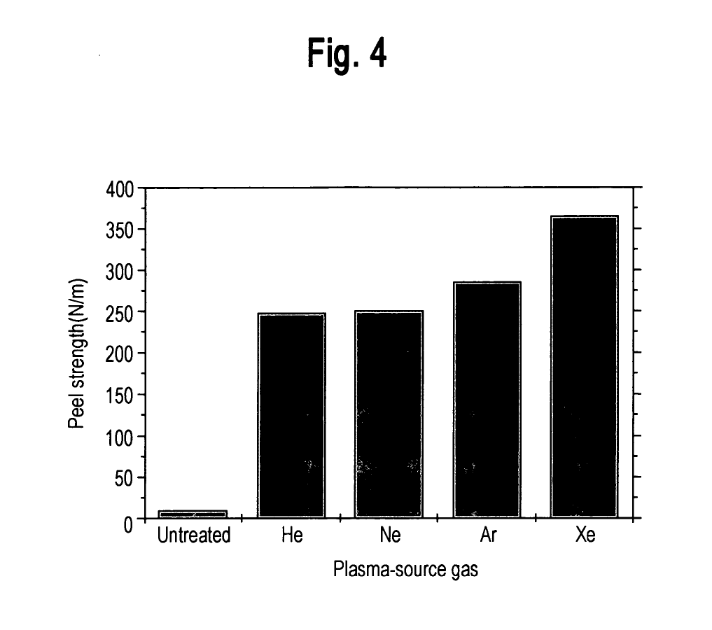

The adhesion of the copper films to the polyimide substrate, in terms of peel strength, was measured. The results are shown in FIG. 4. As shown in FIG. 4, the copper-thin films, which are deposited while implanting plasma ions in the polyimide substrate using such plasma-source gases in accordance with the present invention, show high adhesion to the polyimide substrate. Particularly, when using xenon as a plasma-source gas, the peel strength of the copper film was high, i.e., greater than 350 N/m.

### EXAMPLE 3

The procedure of Example 2 was repeated except that the thickness of the polyimide substrate was 100 μm; an argon gas was used as a plasma-source gas; and the plasma-ion implantation process was performed for 30 seconds to 15 minutes.

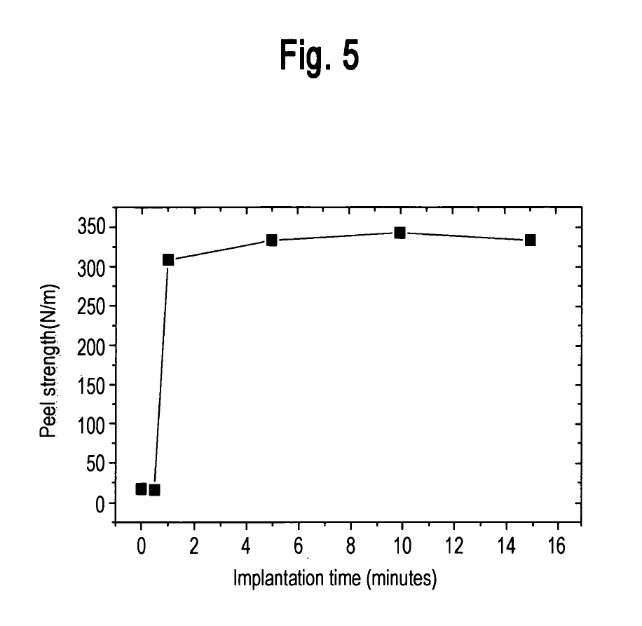

The adhesion of the copper films to the polyimide substrate was measured. The results are shown in FIG. 5. As shown in FIG. 5, the copper-thin films, which are deposited on a polyimide substrate while implanting plasma ions in the polymer substrate for 1 minute or more in accordance with the present invention, has a high peel strength of greater than 300 N/m.

### EXAMPLE 4

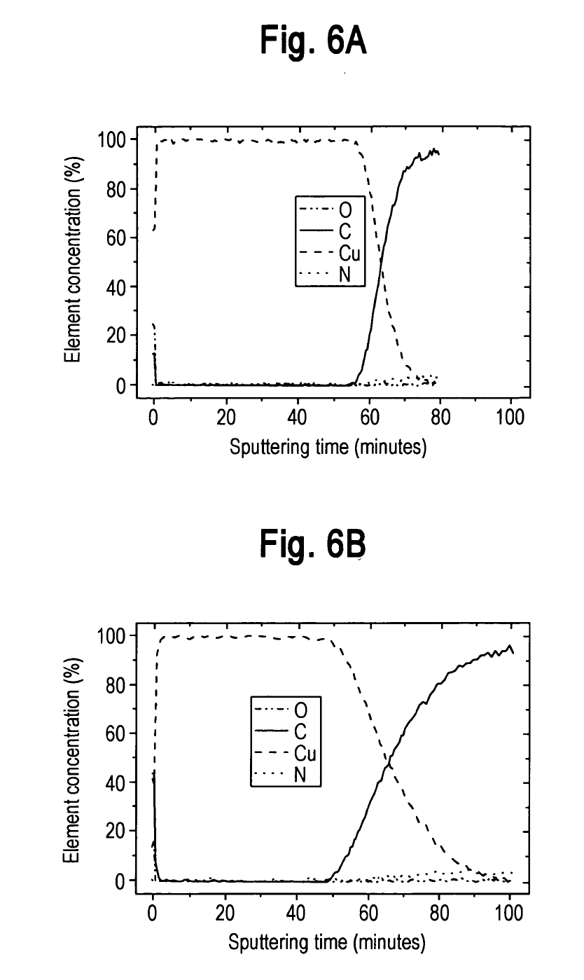

The copper-thin film was deposited on a polyimide substrate for 1 hour while implanting plasma ions in the substrate for 15 minutes as described in Example 1. Further, the copper-thin films as comparative films were deposited without implanting plasma ions in the polyimide substrate but via pre-cleaning or non-treatment of the polyimide substrate using plasma. The Auger distribution was obtained to examine the changes of the interface according to the depth of the deposited copper films, and the results are shown in FIGS. 6a and 6b. As shown FIGS. 6a and 6b, the composed element concentrations around the interface of the copper-coated polyimide product prepared according to the present invention are varied more slowly so as to have a deeper interfacial layer between the copper and polyimide layers (see FIG. 6b). This results in improved adhesion of the metal film to the polymer substrate when compared with the comparative films (see FIG. 6a).

While the present invention has been described with respect to the above specific embodiments, it should be recognized that various modifications and changes may be made to the present invention by those skilled in the art which also fall within the scope of the invention as defined by the appended claims.

1. A method of forming an adherent metal thin-film on a polymer substrate, comprising:
a) placing a polymer substrate on a conductive surface positioned within a vacuum chamber;
b) introducing a plasma-source gas into the vacuum chamber;
c) inducing a plasma from the plasma-source gas;
d) depositing metal atoms on the polymer substrate by applying a negative voltage to a metal target positioned opposite the conductive surface within the vacuum chamber; and
e) applying a negative high-voltage pulse to the conductive surface sufficient to implant ions of the plasma in or below the surface of the polymer substrate.

2. The method of claim 1, wherein the polymer substrate is selected from the group consisting of polyimide, polyethylene terephthalate, polycarbonate, poly(tetrafluoroethylene), polypropylene, polyethylene and combinations thereof.

3. The method of claim 1, wherein the plasma-source gas is selected from the group consisting of argon, helium, neon, krypton, xenon and mixtures thereof.

4. The method of claim 1, wherein the metal is selected from the group consisting of gold, silver, aluminum, stainless steel and combinations thereof.

5. The method of claim 1, wherein the negative voltage applied to the metal target in step (d) is a negative DC voltage ranging from −100 V to −2 kV, or a negative pulse voltage having a pulse width ranging from 1 to 999 ms.

6. The method of claim 1, wherein the negative high-voltage pulse applied to the polymer substrate is a pulse having a voltage ranging from −500 V to −50 kV, a pulse-off voltage ranging from 0 V to −1 kV, a pulse width ranging from 1 to 100 μs, and a pulse frequency ranging from 10 Hz to 10 kHz.

7. The method of claim 1, wherein the negative voltage is applied to the metal target at the same time that the negative high-voltage pulse is applied to the conductive surface.

8. An apparatus for forming an adherent metal-thin film on a polymer substrate, comprising:
a vacuum chamber and a vacuum pump, wherein the vacuum chamber is earthed;
a gas inlet for introducing a plasma-source gas into the vacuum chamber;
an antenna, a radio frequency (RF) power unit and a matching network for inducing a plasma from the plasma-source gas;
a conductive surface for supporting a polymer substrate;
a high-voltage pulse generator for applying a negative high-voltage pulse to the conductive surface sufficient to implant ions of the plasma in or below the surface of the polymer substrate;
a metal target to which a metal source is mounted; and
a power supply for supplying a negative voltage to the metal target.

9. The method of claim 1, wherein the negative high-voltage pulse is applied to the conductive surface after the negative voltage is applied to the metal target.
